(19) United States
(12) Patent Application Publication
(10) Pub. No.: US 2003/0111588 A1
(43) Pub. Date: Jun. 19, 2003

(54) Near-contact optical touch-screen sensor module

(76) Inventor: Pao-Jung Chen, Cupertino, CA (US)

Correspondence Address: PAO-JUNG CHEN, 20872 Sola Street, Cupertino, CA, 95014, US

(21) Appl. No.: 10/025,251

(22) Filed: Dec. 18, 2001

(51) Int. Cl. H01L 27/00

(52) U.S. Cl. 250/208.1

(57) ABSTRACT

A near-contact optical touch-screen sensor module is disclosed in this invention. This sensor module includes a patterned light filtering top glass plate having an array of light filtering window slit holes as the locations for the sensor switches, a LED diode lightened light guide placed in parallel underneath the patterned light filtering top glass plate emitting out a uniform band of light beams transmitting through the window slit holes of the top glass plate, and a serial-scan linear image sensing array supported on a print circuit board having the photo-detecting elements placed closely underneath the neighbor of each of the window slit holes of the top glass plate. The output signals of the image sensing array will indicate if a particular window slit has been touched by the fingertip.

### TECHNICAL FIELD OF THE INVENTION

This invention relates to optical touch-screen sensor switches used to activate commands of electronic input devices. Applications of these optical sensor switches include touch-screen key pads for computer display panels, computer key boards and electronic appliances.

### BACKGROUND OF INVENTION

The current touch-screen key pads use several kinds of sensors, such as resistive type, capacitor type, and infrared optical type sensors. The resistive type sensor is sensitive to resistance change from temperature variations. The capacitor type sensor will not function when non-conductive objects such as rubber gloves are used to touch the screen. The reliability and durability issues of these mechanically pressed resistive type or capacitor type sensors often pose problems for the users.

The infrared optical touch-screen sensor described by Davis Blass in the application note of “Touch Screens for Flat Panel Applications from Sharp Microelectronics of the America,” has several drawbacks, such as coarse resolution, complex to build and develop, parallax, and false triggers. It states that I.R. switches are printed circuit boards with the LED array of emitters and detectors. The layout and design of this board is complex and costly to develop. Since the LED array fits on the front of the display, the IR switch must be made for specific display models. It is difficult to find IR switches in production for various displays. Since it only requires breaking the light beams to activate the switch, anything in the path of the LEDs can trigger the device.

Since the current infrared optical touch sensor uses an infrared LED diode and a photo-detector for each sensor switch. It is costly to build a multiple-switch module, and very difficult to calibrate the LED diodes and the photo-detecting sensors of the module. False triggers are quite common in this infrared touch sensors. Therefore, low cost and reliable non-contact touch-screen sensors are highly desirable for the electronic industry.

### SUMMARY OF THE INVENTION

An infrared optical touch-screen sensor employing digital signal processing software for precise on-off touching detection can be very durable and free of false triggers. The optical touch-screen sensor has to be comparable in physical dimensions to that of a capacitor sensor, especially in thin thickness in order to be mounted on the computer monitor screen or flat display panels. And, it has to be as cost effective as the capacitor sensor.

As illustrated in FIG. 2, this invention, a near-contact optical touch-screen sensor module can achieve all these requirements. It consists of a patterned light-filtering top glass, an LED light guide and a serial scan linear image sensing array operating in photo-charge integration mode.

As illustrated in FIG. 2, the serial scan linear image sensing array for this touch-screen sensor module is consisted of a number of CMOS linear image sensing array chips assembled on the module print circuit board (PCB). As illustrated in FIG. 5 and FIG. 6, each touch-screen sensor switch of the module contains a serial scan CMOS linear image sensing array chip which consists of about 10 photo-detecting pixels with pitches about 500 micrometers between pixels. Each image sensing array chip is cascaded together in operation and functions as a continuous serial scan linear image sensing array on the module. The optical and electrical performance of this array is similar to that of CCD or CIS (contact image sensing) scanner sensing chips. The high dynamic range performance of this array allows intelligent digital signal processing for precise on-off switching detection.

As illustrated in FIG. 2 and FIG. 3, the LED light guide consists of one or more LED diode(s) optically coupled and glued to one or both ends of a plastic half-cylindrical pipe with a cross section similar to a half-circle on top of a rectangular. A certain grating diffracting pattern is crafted at the bottom plate of this half-cylindrical pipe. The LED light guide is used to transform the shape of the LED light beams for this specific application.

The grating diffracting pattern at each cross section diffracts part of the incident longitudinal traveling LED light wave upward. Part of this upward diffracted light will transmit out perpendicularly from the light guide and form a uniform band of light beams along the light guide. This band of light beams emitted from the light guide functions like the band of light beams emitted from a linear closely-packed LED diode array except it uses a very small number of LED diodes. It is cost effective and power saving to use light guide as light source for the touch sensor module. The super bright infrared LED diodes will be used for this light guide. The width of the band of the light beams can be adjusted by changing the cross section shape of the light guide. The irradiating light intensity of the light beams can be easily controlled by adjusting the operating current of the LED diode of the light guide.

As illustrated in FIG. 2 and FIG. 3, the patterned light-filtering top glass is divided into two types of regions, the touch window slits and its surrounding areas. The touch window slits can be any shape: a rectangle, a square or a circle. The window slit area is coated with a film (or paint) of infrared light filter which only allows the infrared light beams radiating from the LED light guide to transmit through, and blocks most of the ambient office light above the top glass to enter into the module. The ambient office light radiating from above the glass toward the window slits is regarded as the interfering light noise to the image sensing array placed underneath the window slits. The rest of the region is coated with light-absorbing black film (or paint) which absorbs both the unwanted incident light from the LED light guide and the ambient light from above the top glass.

As illustrated in FIG. 3 and FIG. 4, because each image sensing array of the touch sensor needs only to detect light beams intensity reflected from the fingertip placed at the window slit, the lens array for reproducing the image in the CIS scanner module as illustrated in FIG. 1 is not required for this touch sensor module. The thickness of the module for the touch sensor is less than the thickness of the CIS scanner module. The photo-detecting elements of the sensing array chip do not need to be placed directly underneath the window slit as illustrated in FIG. 3 and FIG. 4. The position can be optimized to reduce the interfering light noise from the ambient light and the possible false-triggering light noise. The intensity of the light beams can be optimized by a coarse adjustment of the operating current of the LED diode and a fine adjustment of the integration time of the serial scan sensing array. The sensing array is designed to be very sensitive to detecting the LED light beams and is able to output a wide dynamic signal. A low cost microcomputer controller chip with an 8-bit resolution ADC converter can be used for processing the output signals. A simple and effective signal processing software program can be implemented for this smart touch sensor. For example, to detect a robust fingertip contact, for a 100 millisecond duration contact, 10 same output consecutive scans of the sensing array with 10 millisecond of integration time is required. To determine a precise minimum threshold voltage Vth of the touch sensor, and to calibrate the touch sensor switching conditions under various operating environments are also feasible.

### BRIEF DESCRIPTION OF THE DRAWINGS

FIG. 1 illustrates the cross section of a CIS (contact image sensing) scanner module with a short optical path formed by a LED light guide, a selfoc lens array and a linear image sensing array.

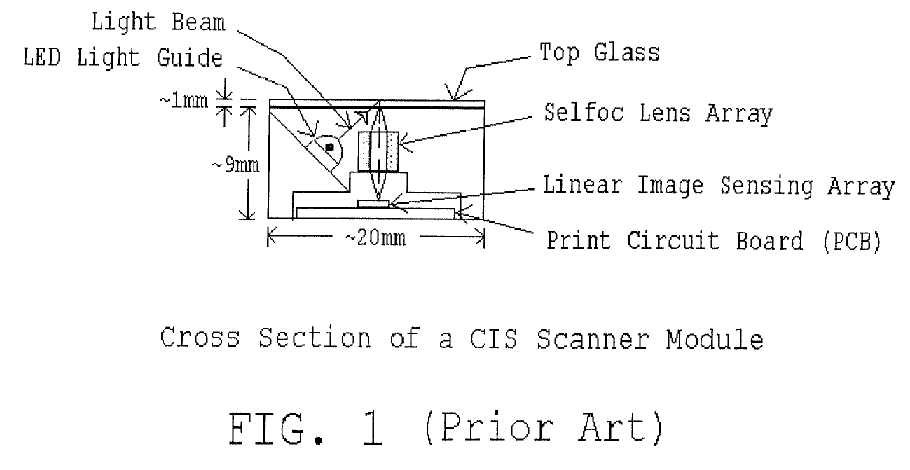

FIG. 2 illustrates the three key components for the optical touch-screen sensor module: a patterned light filtering top glass, a LED light guide, and a serial scan linear image sensing array.

FIG. 3 illustrates the cross section of an optical touch-screen sensor module and the optical path.

FIG. 4 illustrates the optical path from the LED light guide to the linear image sensing array when the finger tip touches the optical touch-screen sensor.

FIG. 5 illustrates the timing signals of a serial scan linear image sensing array, the output signal Vout indicates which touch-screen sensor is being activated.

FIG. 6 illustrates the circuit diagram of a typical CMOS linear image sensing array chip used for the optical touch-screen sensor module.

### DESCRIPTION OF THE PREFERRED EMBODIMENT

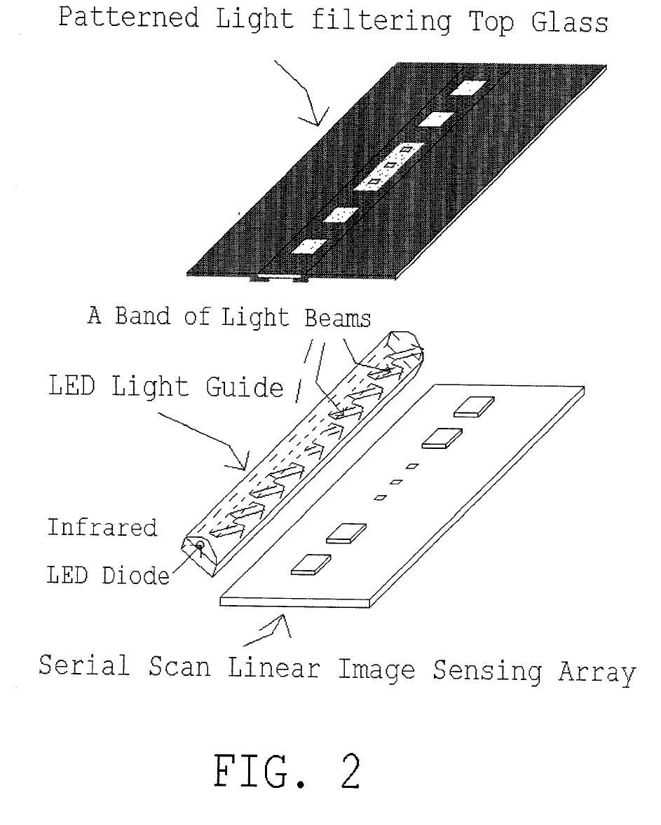

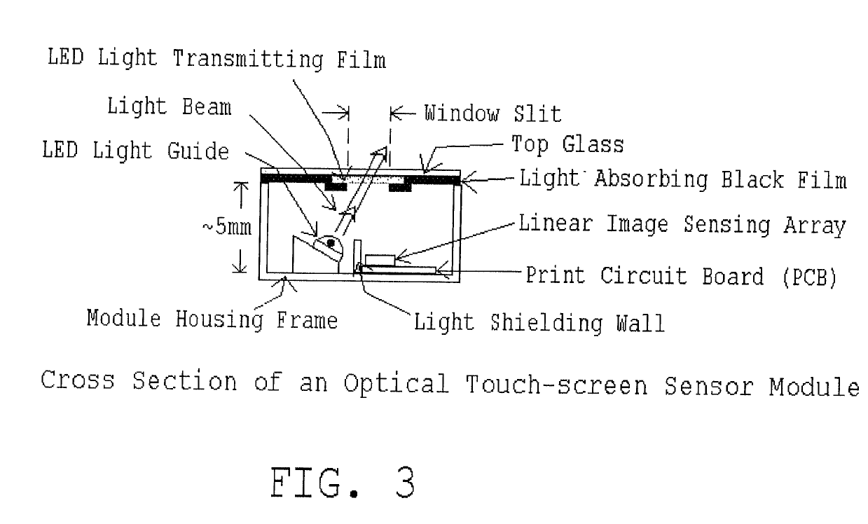

This invention of a near-contact optical touch-screen sensor module comprises a patterned light-filtering top glass, an LED light guide, and a serial-scan linear image sensing array. These three key components of the module are illustrated in FIG. 2. The cross section of a near-contact optical touch-screen sensor module is illustrated in FIG. 3.

Referring to FIG. 2 and FIG. 3, the patterned light-filtering top glass is divided into two types of regions, the touch window slits and its surrounding areas. The touch window slits can be any shape: a rectangle, a square or a circle. The window slit area is coated with a film (or paint) of infrared light filter which only allows the infrared light beams radiating from the LED light guide to transmit through, and blocks most of the ambient office light above the top glass from entering into the module. The ambient office light radiating from above the glass toward the window slits is regarded as the interfering light noise to the image sensing array placed underneath the window slits. The rest of the region is coated with light-absorbing black film (or paint) which absorbs both the unwanted incident light from the LED light guide and the ambient light from above the top glass. Sometimes the manufacturers use pre-patterned computer display screen glass as the top glass of the sensor module.

As illustrated in FIG. 2 and FIG. 3, the LED light guide consists of one or more LED diode(s) optically coupled and glued to one or both ends of a plastic half-cylindrical pipe with a cross section similar to a half-circle on top of a rectangle. A certain grating diffracting pattern is crafted at the bottom plate of this half-cylindrical pipe. The LED light guide is used to transform the shape of the LED light beams for this specific application.

The grating diffracting pattern at each cross section diffracts part of the incident longitudinal traveling LED light wave upward. Part of this upward diffracted light will transmit out perpendicularly from the light guide and form a uniform band of light beams along the light guide. This band of light beams emitted from the light guide functions like the band of light beams emitted from a linear closely-packed LED diode array except it use a very small number of LED diodes. It is very cost effective and power saving to use light guide as light source for the touch sensor module. The super bright infrared LED diodes will be used for this light guide. The width of the band of the light beams can be adjusted by changing the cross section shape of the light guide. The irradiating light intensity of the light beams can be easily controlled by adjusting the operating current of the LED diode of the light guide.

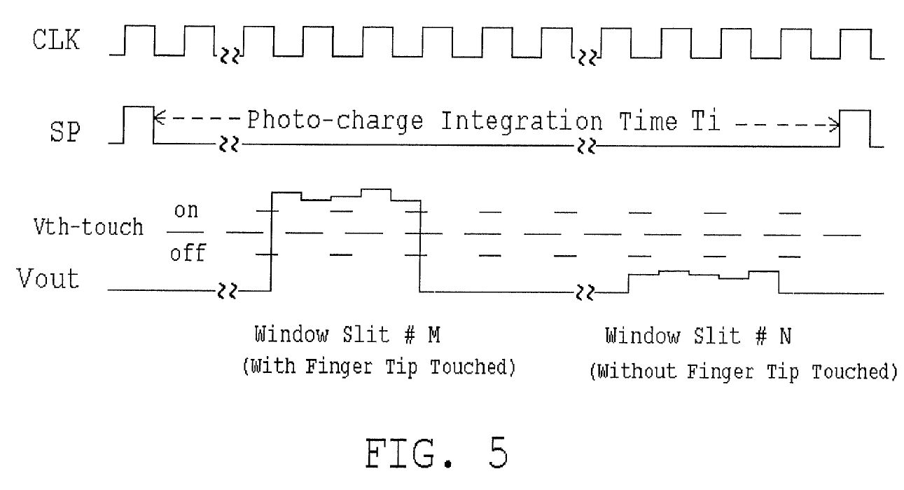

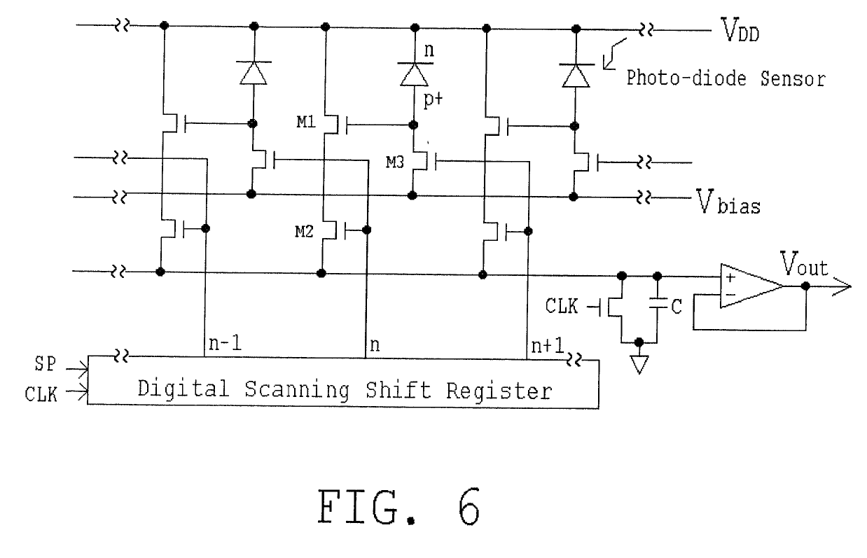

As illustrated in FIG. 2 and FIG. 3, the serial-scan linear image sensing array for this touch-screen sensor module is consisted of a number of CMOS linear image sensing array chips assembled on the module print circuit board (PCB). As illustrated in FIG. 5 and FIG. 6, each touch-screen sensor switch of the module contains a serial scan CMOS linear image sensing array chip which consists of about 10 photo-detecting pixels with a pitches of about 500 micrometers between pixels. Each image sensing array chip is cascaded to each other in operation and functions as a continuous serial scan linear image sensing array on the module. This optical and electrical performance of this array is similar to that of CCD or CIS (contact image sensing) scanner chips. The high dynamic range performance of this array allows precise digital signal processing controls for the on-off status of the sensor. Since the pitch between photo-detecting pixels is very large, this image sensing array chip can be manufactured with low cost standard CMOS process technology.

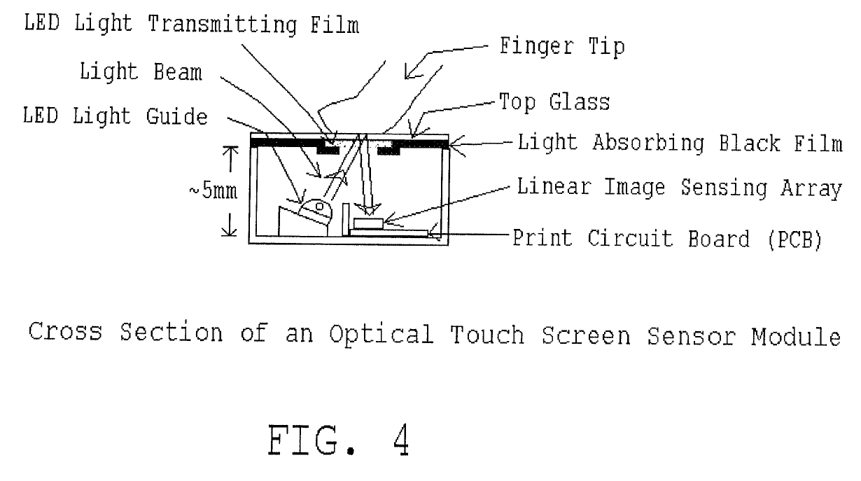

During the operation, while the window slit is not touched by an object, such as the finger tip, the LED light beams will transmit through the filtered window slit glass as illustrated in FIG. 3, and the image sensing detectors will receive very little light from the LED light beams. The sensing array outputs an electrical signal value corresponding to this nearly no light condition as shown in FIG. 5. When the window slit is touched by an object, such as the finger tip, the LED light beams incident upon the finger tip through the window slit glass will be reflected, and the image sensing detectors will receive the reflected LED light beams as shown in FIG. 4. The sensing array will output an electrical signal value corresponding to this light illuminating condition. Therefore, the output signals of the image sensing array will indicate whether a particular window slit has been touched by the finger tip as illustrated in FIG. 5.

The above disclosure is not intended as limiting. Those skilled in the art will readily observe that numerous modifications and alternations of the device may be made while retaining the substance of the invention. Accordingly, the above disclosure should be construed as limited only by the metes and bounds of the appended claims.

I claim:

1. A near-contact optical touch-screen sensor module comprising:
a patterned light filtering top glass plate having an array of light filtering window slit holes;
a LED light guide placed in parallel underneath said patterned light filtering top glass plate having emitting out a uniform band of light beams transmitting through said window slit holes of said top glass plate; and
a serial-scan linear image sensing array supported on a print circuit board having the photo-detecting elements placed closely underneath the neighbor of each of said window slit holes of said top glass plate.

2. A near-contact optical touch-screen sensor module of claim 1 wherein:
said serial-scan linear image sensing array is constructed by cascading a plural number of linear image sensing array chips operating with a photo-charge integration mode; and
each of said image sensing array chips consists of a plural number of photo-detecting elements.

3. A near-contact optical touch-screen sensor module of claim 2 wherein:
said image sensing array chip is placed at least one chip underneath each of said window slit holes of said patterned light filtering top glass plate.

4. A near-contact optical touch-screen sensor module of claim 1 wherein:
said light filtering window slit holes of said patterned light filtering top glass plate are coated with a infrared light filter film (or paint); and
said patterned light filtering top glass plate is coated by a light blocking black film (or paint) except the area of said window slit holes.

5. A near-contact optical touch-screen sensor module of claim 1 wherein:
said LED light guide comprises a single or multiple LED diode(s) optically coupled and glued to one or both ends of a plastic half-cylindrical pipe with a cross section of a lens shape; and
said plastic half-cylindrical pipe having a grating diffracting pattern crafted at a bottom plan of said plastic half-cylindrical pipe to diffract upward part of the incident longitudinal traveling LED light wave emitted from said LED diodes; and
part of said upward diffracted light wave from said part of the incident longitudinal traveling LED light wave emitted from the said LED diodes at each said cross section of said plastic half-cylindrical pipe will transmit perpendicularly out from said LED light guide and form a uniform band of light beams along said LED light guide.
